(19) United States
(12) Patent Application Publication
(10) Pub. No.: US 2013/0027595 A1
(43) Pub. Date: Jan. 31, 2013

(54) SOLID-STATE IMAGING APPARATUS AND AD-CONVERSION OUTPUT BIT COUNT CONTROL METHOD

(71) Applicant: Jun Hashizume, Tokyo (JP)

(72) Inventor: Jun Hashizume, Tokyo (JP)

(73) Assignee: Sony Corporation, Tokyo (JP)

(21) Appl. No.: 13/552,697

(22) Filed: Jul. 19, 2012

(30) Foreign Application Priority Data
Jul. 26, 2011 (JP) 2011-163065

(51) Int. Cl. H04N 5/335

(52) U.S. Cl. 348/302

(57) ABSTRACT

Disclosed herein is a solid-state imaging apparatus including: a pixel array section having pixels laid out two-dimensionally to form a matrix to serve as pixels each used for detecting a physical quantity; an AD conversion section, which stands for an Analog to Digital conversion section, configured to carry out an AD conversion process on an analog pixel signal read out from the pixel array section; and a control section configured to control the AD conversion section on the basis of register values stored in a register, wherein in accordance with a clock frequency used for processing the pixel signal, the control section sets output bit count information expressed by one of the register values to serve as information used for setting an output bit count for the AD conversion process.

### BACKGROUND

In general, the present technology relates to a solid-state imaging apparatus and an AD (Analog to Digital)-conversion output bit count control method. More particularly, the present technology relates to a solid-state imaging apparatus capable of carrying out an AD conversion process producing digital data with an output bit count according to a frame rate requested for the apparatus and capable of executing control of an AD-conversion output bit count and also relates to an AD-conversion output bit count control method adopted by the solid-state imaging apparatus. The AD-conversion output bit count is defined as the number of output bits composing the digital data obtained as the result of the AD conversion process.

In the past, a solid-state imaging apparatus adopting a column AD (Analog to Digital) conversion system was known.

For example, in documents such as Japanese Patent Laid-open No. 2009-33305, there has been proposed a solid-state imaging apparatus employing a reference-voltage supplying circuit of an electrical-charging-and-discharging type. The reference-voltage supplying circuit is a circuit for supplying a reference voltage for an AD conversion process of a column AD conversion system in order to take a countermeasure against an increase of an output bit count set for the AD conversion process. The reference-voltage supplying circuit of the electrical-charging-and-discharging type is a reference-voltage supplying circuit for controlling the gradient of a reference voltage in accordance with a pixel signal. Thus, the proposed solid-state imaging apparatus does not employ a DAC (Digital to Analog Converter) which requires high clock frequency to serve as the reference-voltage supplying circuit for supplying a reference voltage for an AD conversion process.

By the way, in a solid-state imaging apparatus, the frame rate of an image signal output by the solid-state imaging apparatus is determined by considering restrictions including the time period required by analog circuits surrounding pixels to read out signals from the pixels. The time period required to read out signals from the pixels includes a time period it takes to carry out an AD conversion process. That is to say, if the pixel read time period or the AD conversion time period is short, the frame rate can be increased.

Thus, in order to increase the frame rate, it is necessary to decrease the AD conversion time period or the pixel read time period and, in order to decrease the AD conversion time period, it is necessary to reduce the output bit count of the AD conversion process or the time resolution of the AD conversion process.

### SUMMARY

The output bit count of the AD conversion process is determined by a register value stored in a register and the register value is set in accordance with an operation mode of the solid-state imaging apparatus. If the register is set at a register value representing a small output bit count of the AD conversion process in order to meet a request for a high frame rate, however, the quality of the output image will inevitably deteriorate even for a low frame rate which provides a margin to the operation of the solid-state imaging apparatus.

It is thus desired for the present technology addressing the problem described above to provide a solid-state imaging apparatus capable of carrying out an AD conversion process producing digital data with an output bit count according to a requested frame rate.

A solid-state imaging apparatus according to a first mode of the present technology includes:

a pixel array section having pixels laid out two-dimensionally to form a matrix to serve as pixels each used for detecting a physical quantity;

an AD (Analog to Digital) conversion section configured to carry out an AD conversion process on an analog pixel signal read out from the pixel array section; and

a control section configured to control the AD conversion section on the basis of register values stored in a register.

In the solid-state imaging apparatus, in accordance with a clock frequency used for processing the analog pixel signal, the control section sets output bit count information expressed by one of the aforementioned register values to serve as information used for setting an output bit count for the AD conversion process.

It is possible to provide a configuration in which, if the clock frequency is higher than a threshold value determined in advance, the control section sets the output bit count information to reduce the output bit count set for the AD conversion process to be carried out by the AD conversion section.

It is also possible to provide a configuration in which the threshold value determined in advance is a clock frequency fpc corresponding to a maximum frame rate Rmax defined as the maximum value of frame rates for which an AD conversion process can be carried in order to generate a digital image signal having an output bit count set for the AD conversion process.

It is also possible to provide a configuration in which:

the solid-state imaging apparatus is further provided with a signal processing section configured to carry out signal processing determined in advance on a digital image signal generated as a result of the AD conversion process carried out by the AD conversion section; and

the control section controls the signal processing section to adjust a range for the digital image signal having the output bit count reduced by setting of the output bit count information in order to output the digital image signal with a pre-reduction output bit count.

It is also possible to provide a configuration in which:

the signal processing section is controlled to carry out black-level adjustment processing to adjust a black level for the image signal; and

the control section is driven to set black-level adjustment information expressed by one of the register values to serve as information used for setting the black level at a value according to the range adjusted by the signal processing section as the range for the image signal.

It is also possible to provide a configuration in which:

the signal processing section is controlled to correct shading of the image signal; and

the control section is driven to set shading correction information expressed by one of the register values to serve as information used for correcting the shading at a value according to the range adjusted by the signal processing section as the range for the image signal.

It is also possible to provide a configuration in which the control section is driven to set parameter setting information expressed by one of the register values to serve as information used for setting parameters for an analog circuit functioning as a peripheral circuit of the pixel array section so that the parameters for the analog circuit each have a value according to the range adjusted by the signal processing section as the range for the image signal.

It is also possible to provide a configuration in which the clock frequency is a clock frequency used for processing the pixel signals of pixels serving as a smallest processing unit.

A method for controlling an output bit count set for an AD conversion process in accordance with the first mode of the present technology is an AD-conversion output bit count control method adopted in the solid-state imaging apparatus provided by the first mode of the present technology to serve as an apparatus including:

a pixel array section having pixels laid out two-dimensionally to form a matrix to serve as pixels each used for detecting a physical quantity;

an AD (Analog to Digital) conversion section configured to carry out an AD conversion process on an analog pixel signal read out from the pixel array section; and

a control section configured to control the AD conversion section on the basis of register values set in a register.

The AD-conversion output bit count control method includes a step at which, in accordance with a clock frequency used for processing the analog pixel signal, the control section sets output bit count information expressed by one of the aforementioned register values to serve as information used for setting an output bit count for the AD conversion process.

A solid-state imaging apparatus according to a second mode of the present technology includes:

a pixel array section having pixels laid out two-dimensionally to form a matrix to serve as pixels each used for detecting a physical quantity; and

an AD (Analog to Digital) conversion section configured to carry out an AD conversion process in order to generate output bits, the number of which is determined in advance, on an analog pixel signal read out from the pixel array section.

In the solid-state imaging apparatus, the number of the output bits is changed in accordance with a clock frequency.

In the solid-state imaging apparatus according to the first mode of the present technology, in accordance with a clock frequency used for processing the pixel signal of one pixel, the solid-state imaging apparatus sets output bit count information expressed by one of the aforementioned register values to serve as information used for setting an output bit count for the AD conversion process.

In the solid-state imaging apparatus according to the second mode of the present technology, in accordance with a clock frequency, the number of output bits is changed.

In accordance with the first and second modes of the present technology, it is possible to carry out an AD conversion process generating digital data having an output bit count according to a requested frame rate.

### BRIEF DESCRIPTION OF THE DRAWINGS

FIG. 1 is a block diagram showing a typical configuration of a first embodiment implementing a solid-state imaging apparatus according to the present technology;

FIG. 2 is a flowchart representing processing carried out by the solid-state imaging apparatus shown in FIG. 1 to control the output bit count set for an AD conversion process carried out by an AD conversion section employed in the solid-state imaging apparatus;

FIG. 3 is a diagram showing a relation between an internal clock frequency and a frame rate;

FIG. 4 is a block diagram showing a typical configuration of a second embodiment implementing the solid-state imaging apparatus according to the present technology; and

FIG. 5 is a flowchart representing processing carried out by the solid-state imaging apparatus shown in FIG. 4 to control the output bit count set for an AD conversion process carried out by an AD conversion section employed in the solid-state imaging apparatus.

### DETAILED DESCRIPTION OF THE PREFERRED EMBODIMENTS

Embodiments of the present technology are explained by referring to their accompanying drawings as follows.

### 1. First Embodiment

### [Typical Configuration of the Solid-State Imaging Apparatus]

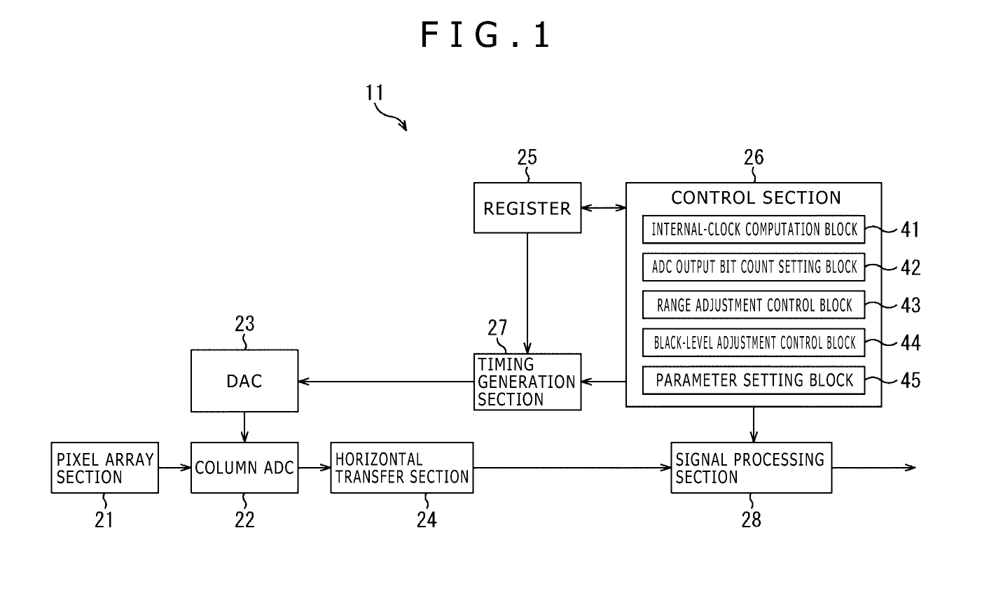

FIG. 1 is a block diagram showing a typical configuration of a first embodiment implementing a solid-state imaging apparatus 11 according to the present technology.

The solid-state imaging apparatus 11 is configured as a CMOS (Complementary Metal Oxide Semiconductor) image sensor. As shown in the figure, the solid-state imaging apparatus 11 includes a pixel array section 21, a column ADC (Analog to Digital Converter) 22, a DAC (Digital to Analog Converter) 23, a horizontal transfer section 24, a register 25, a control section 26, a timing generation section 27 and a signal processing section 28.

The pixel array section 21 has pixels each serving as a photoelectric conversion device for detecting signal electric charge as a physical quantity. The signal electric charge has an amount determined by the quantity of visible light incident to the pixel. The pixels are laid out two-dimensionally to form a matrix. The visible light incident to a pixel is subjected to a photoelectric conversion process of generating an analog pixel signal representing the signal electric charge with an amount determined by the quantity of the visible light. The analog pixel signals generated in the pixel array section 21 are read out for each pixel column of the matrix.

The column ADC 22 carries out an AD conversion process at an output bit count determined in advance on the analog pixel signal, which has been read out from the pixel array section 21 for every pixel column, in order to generate a digital pixel signal having the bit count. Then, the column ADC 22 supplies the digital pixel signal to the horizontal transfer section 24.

On the basis of a timing signal received from the timing generation section 27, the DAC 23 generates a reference voltage and supplies the reference voltage to the column ADC 22. The reference voltage is a voltage having a ramp waveform changing with the lapse of time. The column ADC 22 generates the aforementioned digital pixel signal having a bit count according to a time period during which the analog pixel signal supplied to the column ADC 22 is compared with the reference signal.

The horizontal transfer section 24 sequentially passes on the digital pixel signals, which have each been read out from the column ADC 22 for one of pixel columns, to the signal processing section 28.

The components ranging from the register 25 to the signal processing section 28 are configured to form one LSI (Large Scale Integration) chip.

The register 25 is used for storing register values each representing information on operations carried out by the solid-state imaging apparatus 11. The register values stored in the register 25 are each properly set by the control section 26.

The control section 26 controls operations carried out by the sections employed in the solid-state imaging apparatus 11. If necessary, the control of the operations carried out by the sections employed in the solid-state imaging apparatus 11 is executed by the control section 26 on the basis of the register values stored in the register 25.

In accordance with control executed by the control section 26, the timing generation section 27 generates a timing signal on the basis of a register value stored in the register 25.

The signal processing section 28 adjusts the range for the pixel signal (also referred to as an image signal) received from the horizontal transfer section 24 as a signal having a bit count determined in advance. In addition, the signal processing section 28 also carries out signal processing determined in advance on the image signal received from the horizontal transfer section 24 and outputs the result of the signal processing to recipients such as a display apparatus and a storage apparatus which are not shown in the figure. To put it concretely, the signal processing includes black-level adjustment processing, gain processing and shading correction processing. The black-level adjustment processing is processing carried out in order to adjust the zero level (also referred to as a black level) of the image signal whereas the gain processing is processing carried out in order to adjust the brightness (also referred to as a luminance level) of the image signal. On the other hand, the shading correction processing is processing carried out in order to correct shading generated due to variations of the sensitivities of the pixels provided on the pixel array section 21.

As shown in the figure, the control section 26 includes an internal-clock computation block 41, an ADC output bit count setting block 42, a range adjustment control block 43, a black-level adjustment control block 44 and a parameter setting block 45.

On the basis of a register value stored in the register 25, the internal-clock computation block 41 computes an internal clock frequency which is the frequency of a clock signal used for processing pixel signals of pixels serving as a smallest unit of processing to be carried out on the pixels provided on the pixel array section 21. To put it concretely, for example, the processing to be carried out on the pixels is two-path processing, that is, two-pixel concurrent processing. In this case, the internal clock frequency is the frequency of a clock signal used for processing pixel signals of two pixels. In the case of four-path processing, on the other hand, the internal clock frequency is the frequency of a clock signal used for processing pixel signals of four pixels.

The ADC output bit count setting block 42 compares the internal clock frequency computed by the internal-clock computation block 41 with a threshold value determined in advance. If the result of the comparison indicates that the internal clock frequency is higher than the threshold value determined in advance, the ADC output bit count setting block 42 sets output bit count information serving as a specific one of the register values stored in the register 25 at such a value that the output bit count of the AD conversion process carried out by the column ADC 22 is decreased. The specific register value is a register value used for setting the output bit count which represents the resolution of the AD conversion process.

In other words, the solid-state imaging apparatus 11 changes the output bit count set for the AD conversion process carried out by the column ADC 22 in accordance with the internal clock frequency.

Thus, if the internal clock frequency is higher than the threshold value determined in advance, the column ADC 22 outputs a digital image signal having the reduced output bit count to the signal processing section 28 by way of the horizontal transfer section 24.

The range adjustment control block 43 controls an operation adjusting the range for the image signal processed by the signal processing section 28. To put it concretely, the range adjustment control block 43 controls the signal processing section 28 to adjust the range for the image signal having the output bit count reduced in accordance with the bit count information set by the ADC output bit count setting block 42. The signal processing section 28 adjusts the range in accordance with the control executed by the range adjustment control block 43 in this way so that the signal processing section 28 outputs an image signal having a pre-reduction output bit count.

The black-level adjustment control block 44 sets a register value stored in the register 25 to serve as black-level adjustment information used for adjusting the black level at a value according to the image-signal range adjusted by the signal processing section 28.

The parameter setting block 45 sets a register value stored in the register 25 to serve as parameter setting information used for setting a variety of parameters for an analog circuit not shown in the figure at such a value that the parameters for the analog circuit each have a value according to the image-signal range adjusted by the signal processing section 28. The analog circuit is employed in the solid-state imaging apparatus 11 to serve as a peripheral circuit of the pixel array section 21.

It is to be noted that the components ranging from the pixel array section 21 to the signal processing section 28 can also be constructed on one chip.

### [Processing to Control the Output Bit Count for the AD Conversion Process]

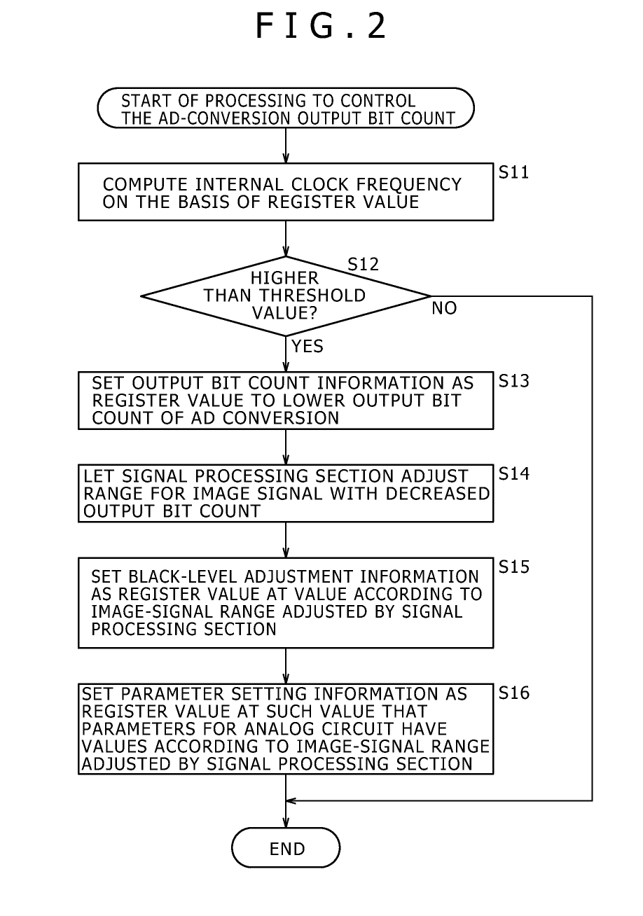

By referring to a flowchart shown in FIG. 2, the following description explains processing carried out by the solid-state imaging apparatus 11 shown in FIG. 1 in order to control the output bit count set for the AD conversion process. In the following description, it is assumed that the output bit count of the AD conversion process carried out by the column ADC 22 has been set at 10 in accordance with the output bit count information which is one of the register values stored in the register 25. As described earlier, the output bit count set for the AD conversion process carried out by the column ADC 22 represents the resolution of the AD conversion process.

As shown in the figure illustrating the flowchart, the flowchart begins with a step S11 at which the internal-clock computation block 41 computes the internal clock frequency in accordance with a register value stored in the register 25.

Then, at the next step S12, the ADC output bit count setting block 42 determines whether or not the internal clock frequency computed by the internal-clock computation block 41 is higher than a threshold value determined in advance.

### [Threshold Value of the Internal Clock Frequency]

The threshold value of the internal clock frequency is explained as follows.

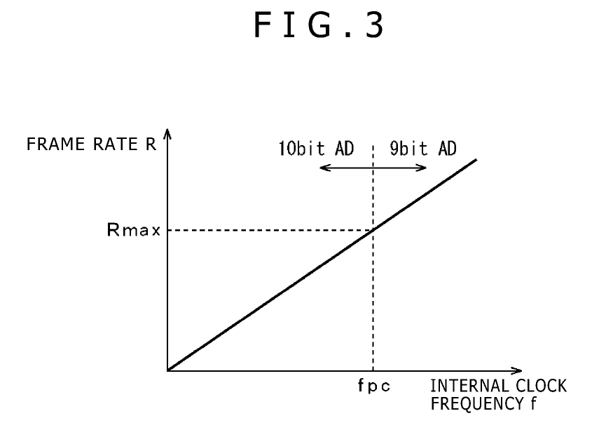

As described above, the frame rate of an output image signal is determined by the time it takes to carry out the AD conversion process. That is to say, the frame rate of an output image signal is determined by the output bit count of the AD conversion process. FIG. 3 is a diagram showing a proportional relation between the internal clock frequency f and the frame rate R.

If the frame rate R requested for an AD conversion process generating a digital signal having an output bit count of 10 is too high for the AD conversion process, that is, if the requested frame rate R exceeds a maximum frame rate Rmax, it is necessary to decrease the output bit count set for the AD conversion process to 9. In this case, the maximum frame rate Rmax is defined as the maximum value of frame rates for which the AD conversion process can be carried out in order to generate a digital signal having an output bit count of 10. In other words, if the internal clock frequency f is higher than a frequency fpc corresponding to the maximum frame rate Rmax in accordance with the relation shown in FIG. 3, it is necessary to decrease the output bit count set for the AD conversion process to 9. As described above, the maximum frame rate Rmax is the maximum value of frame rates for which the AD conversion process can be carried out in order to generate a digital signal having the output bit count of 10.

Thus, the threshold value for the internal clock frequency f is the internal clock frequency fpc corresponding to the maximum frame rate Rmax defined as the maximum value of frame rates for which the AD conversion process can be carried out in order to generate a digital signal having an output bit count set for the AD conversion process.

As is obvious from the flowchart shown in FIG. 2, if the result of the determination carried out at the step S12 indicates that the internal clock frequency is higher than the threshold value determined in advance, the flow of the control processing goes on to a step S13 at which the ADC output bit count setting block 42 sets output bit count information at a value reducing the output bit count set for the AD conversion process. In this case, the ADC output bit count setting block 42 sets the output bit count information at a value reducing the output bit count set for the AD conversion process to 9. As described earlier, the output bit count information is one of register values stored in the register 25.

With the output bit count information set as a register value in the register 25 as described above, the timing generation section 27 supplies a timing signal according to the output bit count information to the DAC 23 and the DAC 23 thus outputs a reference voltage according to the timing signal to the column ADC 22. As a result, the column ADC 22 outputs a digital image signal having a bit count of 9 according to the reference voltage.

Then, at the next step S14, the range adjustment control block 43 controls the signal processing section 28 to adjust the range for the image signal having the output bit count reduced in accordance with the output bit count information set by the ADC output bit count setting block 42. The signal processing section 28 adjusts the range in accordance with the control executed by the range adjustment control block 43 in this way so that the signal processing section 28 outputs an image signal having a pre-reduction output bit count. Thus, the signal processing section 28 adjusts the range for the digital image signal having an output bit count of 9 in order to output an image signal having an output bit count of 10. It is to be noted that the signal processing section 28 may adjust the range with a timing before or after processing carried out to adjust the black level.

Subsequently, at the next step S15, the black-level adjustment control block 44 sets black-level adjustment information expressed by one of the register values stored in the register 25 at a value according to the image-signal range adjusted by the signal processing section 28. To put it concretely, if the signal processing section 28 adjusts the range of the image signal with a timing before the processing carried out to adjust the black level, the black-level adjustment control block 44 sets the black-level adjustment information at a value according to the image signal having an output bit count of 10. This is because the processing to adjust the black level is carried out for the image signal having an output bit count of 10. If the signal processing section 28 adjusts the range of the image signal with a timing after the processing carried out to adjust the black level, on the other hand, the black-level adjustment control block 44 sets the black-level adjustment information at a value according to the image signal having an output bit count of 9. This is because the processing to adjust the black level is carried out for the image signal having an output bit count of 9.

Thus, the signal processing section 28 carries out the processing to adjust the black level in accordance with the range for the image signal.

Then, at the next step S16, the parameter setting block 45 sets parameter setting information expressed by one of the register values stored in the register 25 at such a value that a variety of parameters for an analog circuit each have a value according to the image-signal range adjusted by the signal processing section 28. The analog circuit is employed in the solid-state imaging apparatus 11 to serve as a peripheral circuit of the pixel array section 21.

Thus, the analog circuit of the pixel array section 21 carries out an operation according to the image-signal range adjusted by the signal processing section 28.

In accordance with the control processing described above, if the internal clock frequency is higher than the threshold value determined in advance, the output bit count information is set at a value reducing the output bit count set for the AD conversion process. It is thus possible to carry out an AD conversion process for generating a digital image signal having an output bit count according to a requested frame rate even if the requested frame rate cannot be reached by carrying out the AD conversion process at the current output bit count.

As described above, in accordance with the image-signal range adjusted by the signal processing section 28, the signal processing section 28 is controlled to adaptively carry out the processing to adjust the black level. However, the signal processing section 28 can also be controlled to adaptively carry out processing to correct shading as described as follows.

### 2. Second Embodiment

### [Typical Configuration of the Solid-State Imaging Apparatus]

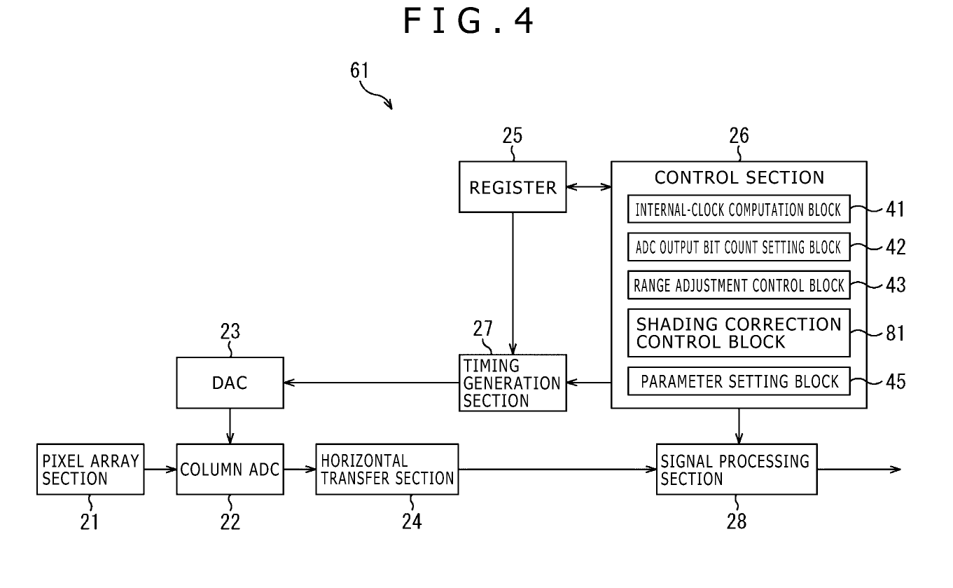

FIG. 4 is a block diagram showing a typical configuration of a second embodiment implementing a solid-state imaging apparatus 61 according to the present technology.

It is to be noted that each component employed in the solid-state imaging apparatus 61 shown in FIG. 4 to serve as a component having a function identical with that of its counterpart component employed in the solid-state imaging apparatus 11 shown in FIG. 1 is given the same name as the counterpart component and denoted by the same reference numeral as the counterpart component. In addition, explanation of such identical components is properly eliminated from the following description.

The solid-state imaging apparatus 61 shown in FIG. 4 is different from the solid-state imaging apparatus 11 shown in FIG. 1 in that the solid-state imaging apparatus 61 shown in FIG. 4 employs a shading correction control block 81 in place of the black-level adjustment control block 44 employed in the solid-state imaging apparatus 11 shown in FIG. 1.

The shading correction control block 81 sets shading correction information at a value according to the image-signal range adjusted by the signal processing section 28. Represented by one of the register values stored in the register 25, the shading correction information is information used for correcting shading.

### [Processing to Control the Output Bit Count for the AD Conversion Process]

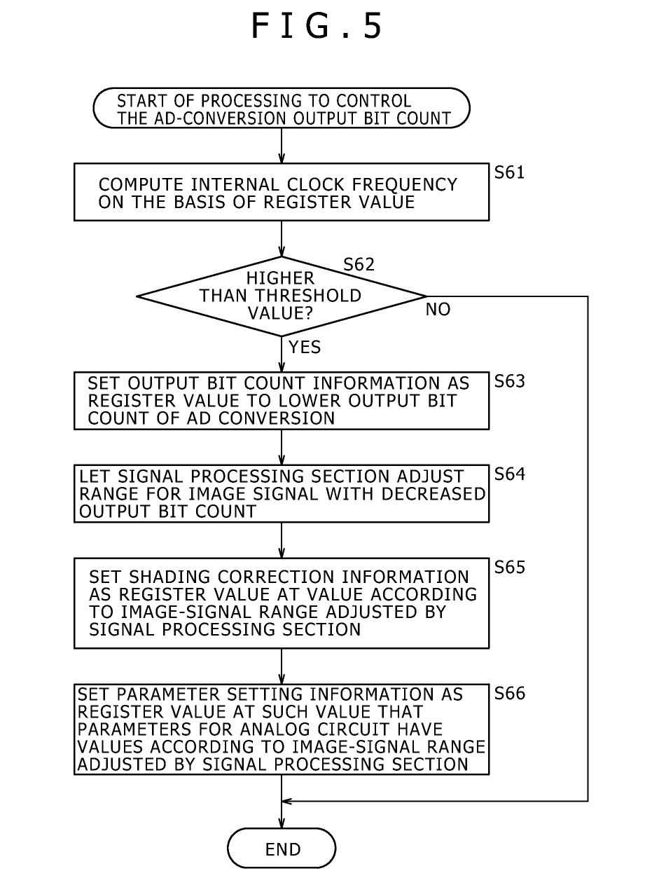

Next, by referring to a flowchart shown in FIG. 5, the following description explains processing carried out by the solid-state imaging apparatus 61 shown in FIG. 4 in order to control the output bit count set for the AD conversion process.

It is to be noted that processes carried out at steps S61 to S64 and a step S66 which are included in the flowchart shown in FIG. 5 are identical with respectively the processes carried out at the steps S11 to S14 and the step S16 which are included in the flowchart shown in FIG. 2. For this reason, explanation of the processes carried out at the steps S61 to S64 and the step S66 is properly eliminated from the following description.

At a step S65 of the flowchart shown in FIG. 5, the shading correction control block 81 sets shading correction information expressed by one of the register values stored in the register 25 at a value according to the image-signal range adjusted by the signal processing section 28. It is to be noted that, since the signal processing section 28 adjusts the range of the image signal before the processing to correct shading, the shading correction processing is carried out on an image signal having an output bit count of 10. Accordingly, the shading correction control block 81 sets the shading correction information at a value according to the image signal having an output bit count of 10.

Thus, the signal processing section 28 carries out the shading correction processing according to the range for the image signal.

Also by carrying out the processing to control the output bit count for the AD conversion process in accordance with the flowchart shown in FIG. 5, it is possible to demonstrate the same effects as those of the processing performed to control the output bit count for the AD conversion process in accordance with the flowchart shown in FIG. 2.

As described above, processing is carried out in order to change the output bit count set for the AD conversion process from 10 to 9. It is to be noted, however, that the change of the output bit count can be any arbitrary change as long as the change is from a certain output bit count to an output bit count smaller than the certain output bit count. For example, the processing can also carried out in order to change the output bit count set for the AD conversion process from 10 to 8.

In addition, also as described above, the processing is carried out for a case in which the requested frame rate is higher than the maximum frame rate. It is to be noted, however, that processing can also be carried out for a case in which the requested frame rate is lower than the threshold value determined in advance. Then, the output bit count set for the AD conversion process is adjusted by increasing the output bit count. In this case, the threshold value determined in advance is an internal clock frequency corresponding to the maximum frame rate defined as the maximum value of frame rates for which an AD conversion process can be carried in order to generate a digital signal having the output bit count set for the AD conversion process.

It is to be noted that the embodiments described above have been exemplified by a case in which the present technology is applied to a CMOS image sensor employing unit pixels laid out to form a matrix to serve as unit pixels each used for detecting signal electric charge having an amount according to the quantity of visible light incident to the pixel as a physical quantity. However, applications of the present technology are by no means limited to the applications to such a CMOS image sensor. That is to say, the present technology can also be applied to ordinary solid-state imaging apparatus adopting the column system in which a column processing section is provided for each pixel column of the matrix of the pixel array section.

In addition, applications of the present technology are by no means limited to the applications to a solid-state imaging device for detecting a distribution of quantities of incident visible light in order to take an image. That is to say, the present technology can also be applied to a solid-state imaging device for detecting a distribution of quantities of typically incident infrared rays, incident X rays or incident particles in order to take an image as well as a solid-state imaging apparatus in a broader sense. A typical example of the solid-state imaging apparatus in a broader sense is a general solid-state imaging apparatus (also referred to as a physical-quantity distribution detection apparatus) for detecting a distribution of another physical quantity such as a pressure or a static capacitance in order to take an image as is the case with a fingerprint detection sensor.

It is to be noted that implementations of the present technology are by no means limited to the embodiments described above. That is to say, a variety of changes can be further made to the embodiments as long as the changes do not deviate from a range of essentials of the present technology.

In addition, the present technology can also be realized into the following implementations:

(1) A solid-state imaging apparatus including:

a pixel array section having pixels laid out two-dimensionally to form a matrix to serve as pixels each used for detecting a physical quantity;

an AD (Analog to Digital) conversion section configured to carry out an AD conversion process on an analog pixel signal read out from the pixel array section; and

a control section configured to control the AD conversion section on the basis of register values stored in a register,

wherein, in accordance with a clock frequency used for processing the analog pixel signal, the control section sets output bit count information expressed by one of the register values to serve as information used for setting an output bit count for the AD conversion process.

(2) The solid-state imaging apparatus according to implementation (1) wherein, if the clock frequency is higher than a threshold value determined in advance, the control section sets the output bit count information to reduce the output bit count set for the AD conversion process to be carried out by the AD conversion section.

(3) The solid-state imaging apparatus according to implementation (2) wherein the threshold value determined in advance is a clock frequency corresponding to a maximum frame rate defined as the maximum value of frame rates obtainable during a time period required for carrying out an AD conversion process in order to generate a digital image signal having an output bit count set for the AD conversion process.

(4) The solid-state imaging apparatus according to implementation (2) or (3), the solid-state imaging apparatus further provided with a signal processing section configured to carry out signal processing determined in advance on a digital image signal generated as a result of the AD conversion process carried out by the AD conversion section, wherein the control section controls the signal processing section to adjust a range for the digital image signal having an output bit count reduced by setting of the output bit count information in order to output the digital image signal with a pre-reduction output bit count.

(5) The solid-state imaging apparatus according to implementation (4) wherein:

the signal processing section carries out black-level adjustment processing to adjust a black level for the image signal; and

the control section sets black-level adjustment information expressed by one of the register values to serve as information used for setting the black level at a value according to the range adjusted by the signal processing section as the range for the image signal.

(6) The solid-state imaging apparatus according to implementation (4) wherein:

the signal processing section corrects shading of the image signal; and

the control section sets shading correction information expressed by one of the register values to serve as information used for correcting the shading at a value according to the range adjusted by the signal processing section as the range for the image signal.

(7) The solid-state imaging apparatus according to any one of implementations (4) to (6) wherein the control section sets parameter setting information expressed by one of the register values to serve as information used for setting parameters for an analog circuit functioning as a peripheral circuit of the pixel array section so that the parameters for the analog circuit each have a value according to the range adjusted by the signal processing section as the range for the image signal.

(8) The solid-state imaging apparatus according to any one of implementations (1) to (7) wherein the clock frequency is a clock frequency used for processing the pixel signals of the pixels serving as a smallest processing unit.

(9) An AD (Analog to Digital)-conversion output bit count control method serving as a method for controlling an output bit count set for an AD conversion process to be carried out by a solid-state imaging apparatus including:

a pixel array section having pixels laid out two-dimensionally to form a matrix to serve as pixels each used for detecting a physical quantity;

an AD conversion section configured to carry out the AD conversion process on an analog pixel signal read out from the pixel array section; and

a control section configured to control the AD conversion section on the basis of register values set in a register,

the AD-conversion output bit count control method including driving the control section to set output bit count information, which is expressed by one of the register values to serve as information used for setting the output bit count for the AD conversion process, in accordance with a clock frequency used for processing the analog pixel signal.

(10) A solid-state imaging apparatus including:

a pixel array section having pixels laid out two-dimensionally to form a matrix to serve as pixels each used for detecting a physical quantity; and

an AD (Analog to Digital) conversion section configured to carry out an AD conversion process in order to generate output bits, the number of which is determined in advance, on an analog pixel signal read out from the pixel array section,

wherein the number of the output bits is changed in accordance with a clock frequency.

The present disclosure contains subject matter related to that disclosed in Japanese Priority Patent Application JP 2011-163065 filed in the Japan Patent Office on Jul. 26, 2011, the entire content of which is hereby incorporated by reference.

What is claimed is:

1. A solid-state imaging apparatus comprising:
a pixel array section having pixels laid out two-dimensionally to form a matrix to serve as pixels each used for detecting a physical quantity;
an AD conversion section, which stands for an Analog to Digital conversion section, configured to carry out an AD conversion process on an analog pixel signal read out from said pixel array section; and
a control section configured to control said AD conversion section on the basis of register values stored in a register, wherein
in accordance with a clock frequency used for processing said pixel signal, said control section sets output bit count information expressed by one of said register values to serve as information used for setting an output bit count for said AD conversion process.

2. The solid-state imaging apparatus according to claim 1 wherein, if said clock frequency is higher than a threshold value determined in advance, said control section sets said output bit count information to reduce said output bit count set for said AD conversion process to be carried out by said AD conversion section.

3. The solid-state imaging apparatus according to claim 2 wherein said threshold value determined in advance is a clock frequency corresponding to a maximum frame rate defined as the maximum value of frame rates obtainable during a time period required for carrying out an AD conversion process in order to generate a digital image signal having an output bit count set for said AD conversion process.

4. The solid-state imaging apparatus according to claim 2, said solid-state imaging apparatus further comprising
a signal processing section configured to carry out signal processing determined in advance on a digital image signal generated as a result of said AD conversion process carried out by said AD conversion section,
wherein said control section controls said signal processing section to adjust a range for said digital image signal having an output bit count reduced by setting of said output bit count information in order to output said digital image signal with a pre-reduction output bit count.

5. The solid-state imaging apparatus according to claim 4 wherein:
said signal processing section carries out black-level adjustment processing to adjust a black level for said image signal; and
said control section sets black-level adjustment information expressed by one of said register values to serve as information used for setting said black level at a value according to said range adjusted by said signal processing section as said range for said image signal.

6. The solid-state imaging apparatus according to claim 4 wherein:
said signal processing section corrects shading of said image signal; and
said control section sets shading correction information expressed by one of said register values to serve as information used for correcting said shading at a value according to said range adjusted by said signal processing section as said range for said image signal.

7. The solid-state imaging apparatus according to claim 4 wherein said control section sets parameter setting information expressed by one of said register values to serve as information used for setting parameters for an analog circuit functioning as a peripheral circuit of said pixel array section so that said parameters for said analog circuit each have a value according to said range adjusted by said signal processing section as said range for said image signal.

8. The solid-state imaging apparatus according to claim 1 wherein said clock frequency is a clock frequency used for processing said pixel signals of said pixels serving as a smallest processing unit.

9. An AD-conversion output bit count control method, which stands for an Analog to Digital-conversion output bit count control method, serving as a method for controlling an output bit count set for an AD conversion process to be carried out by a solid-state imaging apparatus including
a pixel array section having pixels laid out two-dimensionally to form a matrix to serve as pixels each used for detecting a physical quantity,
an AD conversion section configured to carry out said AD conversion process on an analog pixel signal read out from said pixel array section, and
a control section configured to control said AD conversion section on the basis of register values set in a register,
said AD-conversion output bit count control method comprising:
driving said control section to set output bit count information, which is expressed by one of said register values to serve as information used for setting said output bit count for said AD conversion process, in accordance with a clock frequency used for processing said pixel signal.

10. A solid-state imaging apparatus comprising:
a pixel array section having pixels laid out two-dimensionally to form a matrix to serve as pixels each used for detecting a physical quantity; and
an AD conversion section, which stands for an Analog to Digital section, configured to carry out an AD conversion process in order to generate output bits, the number of which is determined in advance, on an analog pixel signal read out from said pixel array section,
wherein the number of said output bits is changed in accordance with a clock frequency.
